(19) United States
(12) Patent Application Publication
(10) Pub. No.: US 2016/0049569 A1
(43) Pub. Date: Feb. 18, 2016

(54) THERMOELECTRIC POWER SOURCE FOR PERSONAL ELECTRONICS AND WEARABLE ELECTRONIC DEVICES HAVING SAME

(71) Applicant: Barry E. Negrin, New York, NY (US)

(72) Inventor: Barry E. Negrin, New York, NY (US)

(21) Appl. No.: 14/825,049

(22) Filed: Aug. 12, 2015

Related U.S. Application Data
(60) Provisional application No. 62/036,974, filed on Aug. 13, 2014.

(51) Int. Cl. H01L 35/30; G06F 1/16; H02J 7/00; H01L 35/32

(52) U.S. Cl. CPC H01L 35/30; H01L 35/32; G06F 1/163; H02J 7/0052

(57) ABSTRACT

A wearable electronic device, an alternative power source for a wearable electronic device, and a method of powering a wearable electronic device, are provided. The device includes a casing and electronics disposed therein. A thermoelectric generator such as a Peltier device is provided in electrical communication with the electronics; a heat absorbing side is in thermal communication with the wearer of the wearable electronic device when the device is worn. When the electronic device is worn by a wearer, body heat from the wearer is absorbed by the heat absorbing side and converted into electricity by the Peltier device which at least partially powers the electronics. At least one fin is provided in thermal communication with the heat releasing side, drawing heat away from the Peltier device. The fin is disposed substantially through the casing with the distal end terminating substantially at a top side of the casing.

### RELATED APPLICATIONS

Priority is claimed from U.S. Provisional Patent Application No. 62/036,974 entitled “PELTIER POWER SOURCE FOR WEARABLE ELECTRONICS” filed Aug. 13, 2014, the entire teachings of which are hereby incorporated by reference herein.

### BACKGROUND OF THE INVENTION

1. Field of the Invention

The invention relates to consumer electronics, and more specifically to primary and supplemental power sources for personal consumer electronics such as smart watches, eyeglass computers, and cell phones.

2. Description of the Related Art

Portable data assistants (PDAs) have been in existence for roughly 30 years, a subset of which are cellular telephones with internet browsing capability, also known as “smart phones.” Smart phones have been a hugely successful segment of the consumer electronics industry, however a rampant problem across smart phone manufacturers is poor battery life. Smart phones have the capability to perform nearly all of the tasks of a desktop computer, however the more the device is used and the more apps are running simultaneously, the quicker the battery is drained. This phenomenon is often at the expense of being able to use the device as an actual phone, either in case of an emergency, or to be reached by another, or the like. Regardless of the desired usage, often a smart phone runs out of charge within a 24-hour period. Failure to remember to plug it in for charging at the end of the day usually results in a non-functioning unpowered smart phone some time the next day.

A new area for consumer electronic devices that is similar to smart phones is wearable electronics, and one example of wearable electronics is the smart watch. It is essentially similar to a smart phone but smaller and wearable on one's wrist. Some smart watches are merely wrist accessories for smart phones that do not function separately from smart phones and must communicate wirelessly (e.g., NFC, Bluetooth, etc.) with a nearby smart phone. Other smart watches function independently from a smart phone and can perform many of the same functions as a smart phone, e.g., browse the internet, make calls, send text messages, etc. In either case, smart watches are currently seen as “the next big thing” in consumer electronics.

However, the same problem that plagues smart phones also plagues smart watches: poor battery life. In fact, because the typical smart watch is significantly smaller than the smart phone (e.g., a Samsung Galaxy Gear 2 Neo smart watch is 37 mm×59 mm×10 mm thick, whereas a Samsung Galaxy S5 smart phone is 142 mm×72.5 mm×8 mm, almost five times the size of the Gear 2 Neo), the battery of a smart watch is significantly smaller, and the battery life is also significantly shorter. Absent a revolution in battery chemistry technology, there is a widely felt need in the wearable electronics industry for a way to power the devices so that they can be used for longer periods of time.

In addition, people sometimes “wear” their cell phones on their person via, e.g., an arm band or resilient sleeve or the like, e.g., while exercising. There is a long-felt need to improve that modality of usage as well.

### SUMMARY OF THE INVENTION

The invention includes a wearable electronics power source for personal electronics comprising a thermoelectric generator such as a Peltier tile having a heat absorbing side disposable in thermal communication with the user's skin and a heat releasing side, wherein heat from the user's body enters the Peltier tile and generates electricity which powers the wearable/personal electronics.

Optionally, the wearable electronic device has a rechargeable battery and the Peltier tile charges the battery whenever the device is worn.

Preferably, the power source includes at least one fin having a proximal end in thermal communication (e.g., conduction, convection, radiation, etc.) with the heat absorbing side of the Peltier tile and a distal end in thermal communication with ambient air. Optionally, the at least one fin is disposed in and/or through a casing of the wearable electronic device. The fin or fins may take any convenient or practical shape and may be continuous along the length of a side of the casing and Peltier tile or the entirety of the perimeter of the casing and Peltier tile or may be discrete and multiple in nature. In the latter case, the multiple discrete fins may be of any practical cross-sectional shape, e.g., circular, square, rectangular, hexagonal, etc. Because the top(s) of the fin(s) is/are optionally visible from the top surface of the device, the fin(s) can be made into decorative shapes as well, e.g., letters spelling the name of the model/brand of the watch, designs, patterns, etc.

The invention also includes a wearable electronic device having a rechargeable battery and a thermoelectric generator such as a Peltier tile having a heat absorbing side disposable in contact with the user's skin and a heat releasing side, wherein heat from the user's body enters the Peltier tile and generates electricity which charges the rechargeable battery and/or powers the wearable electronics.

The invention includes a wearable electronic device having a casing and electronics disposed within the casing. A thermoelectric generator is in electrical communication with the electronics and having a heat absorbing side in thermal communication with the wearer of the wearable electronic device when the wearable electronic device is being worn, and a heat releasing side. When the wearable electronic device is worn by a wearer, body heat from the wearer is absorbed by the heat absorbing side and converted into electricity by the thermoelectric generator which at least partially powers the electronics. A battery is optionally provided in electrical communication with the electronics and the thermoelectric generator; electricity generated by the thermoelectric generator is provided to the battery.

Preferably, at least one fin is provided in thermal communication with the heat releasing side, drawing heat away from the thermoelectric generator when the wearable electronic device is being worn. The fin has a proximal end in thermal communication with the heat releasing side and a distal end in thermal communication with ambient air. The fin is preferably disposed substantially through the casing with the distal end terminating substantially at a top side of the casing.

The thermoelectric generator is, in one aspect of the invention, a supplemental power source, and the electricity generated by the thermoelectric generator is substantially sufficient to maintain the battery in equilibrium so that the battery is being charged at substantially the same rate that the battery is discharging in powering the wearable electronic device. In another aspect of the invention, the thermoelectric generator is a supplemental power source and the electricity generated by the thermoelectric generator is slowing the discharge rate of the battery. In another aspect of the invention, the thermoelectric generator generates enough electricity to act as a primary power source for the wearable electronic device.

The wearable electronic device includes at least one of a smart watch or an eyeglass computer. The thermoelectric generator preferably includes a Peltier device.

In another aspect of the invention, the invention is a power source for a wearable/personal electronic device having a casing and electronics disposed within the case. The power source includes a thermoelectric generator in electrical communication with the electronics and having a heat absorbing side in thermal communication with the wearer of the wearable electronic device when the wearable electronic device is being worn, and a heat releasing side. When the wearable/personal electronic device is worn by a wearer, body heat from the wearer is absorbed by the heat absorbing side and converted into electricity by the thermoelectric generator which at least partially powers the electronics.

Optionally, a battery is included in electrical communication with the electronics and the thermoelectric generator, wherein electricity generated by the thermoelectric generator is provided to the battery.

Preferably, at least one fin is provided in thermal communication with the heat releasing side, drawing heat away from the thermoelectric generator when the wearable electronic device is being worn. The fin preferably has a proximal end in thermal communication with the heat releasing side and a distal end in thermal communication with ambient air. The fin is preferably disposed substantially through the casing with the distal end terminating substantially at a top side of the casing.

In the inventive power source for a wearable electronic device, the thermoelectric generator preferably includes a Peltier device.

In another aspect of the invention, the invention includes a method of powering a wearable/personal electronic device having a casing and electronics disposed within the casing. The inventive method includes the steps of: providing a thermoelectric generator in electrical communication with the electronics and having a heat absorbing side in thermal communication with the wearer of the wearable/personal electronic device when the wearable/personal electronic device is being worn, and a heat releasing side; absorbing body heat from the wearer into the thermoelectric generator; converting the absorbed body heat into electricity by the thermoelectric generator; and at least partially powering the electronics with the electricity generated by the thermoelectric generator.

Optionally, the inventive method includes the steps of providing a battery in electrical communication with the electronics and the thermoelectric generator; and providing the electricity generated by the thermoelectric generator to the battery. Preferably, the inventive method includes the steps of: providing at least one fin, in thermal communication at a proximal end with the heat releasing side; and drawing heat away from the thermoelectric generator via the fin. The method preferably further includes the step of disposing a distal end of the fin in thermal communication with ambient air.

### BRIEF DESCRIPTION OF THE DRAWINGS

FIG. 1 is a sectional perspective schematic of a Peltier device/tile.

FIG. 2 is a side elevational schematic of a Peltier device/tile.

FIG. 3A is a front schematic of a smart watch in accordance with the invention.

FIG. 3B is a partially exploded side perspective schematic of a smart watch in accordance with the invention.

FIG. 4 is a side schematic of a Peltier power source for wearable electronics in accordance with the invention.

FIG. 5 is a side schematic of a Peltier power source for wearable electronics in accordance with the invention.

FIG. 6 is a top schematic of a Peltier power source for wearable electronics in accordance with the invention of FIG. 5.

FIG. 7 is a schematic of a circuit diagram of a Peltier power source for wearable electronics in accordance with the invention.

FIG. 8 is a side schematic of another circuit diagram of a Peltier power source for wearable electronics in accordance with the invention.

FIG. 9 is a front perspective of another wearable electronic device having a Peltier power source in accordance with the invention.

### DETAILED DESCRIPTION OF THE INVENTION AND DRAWINGS

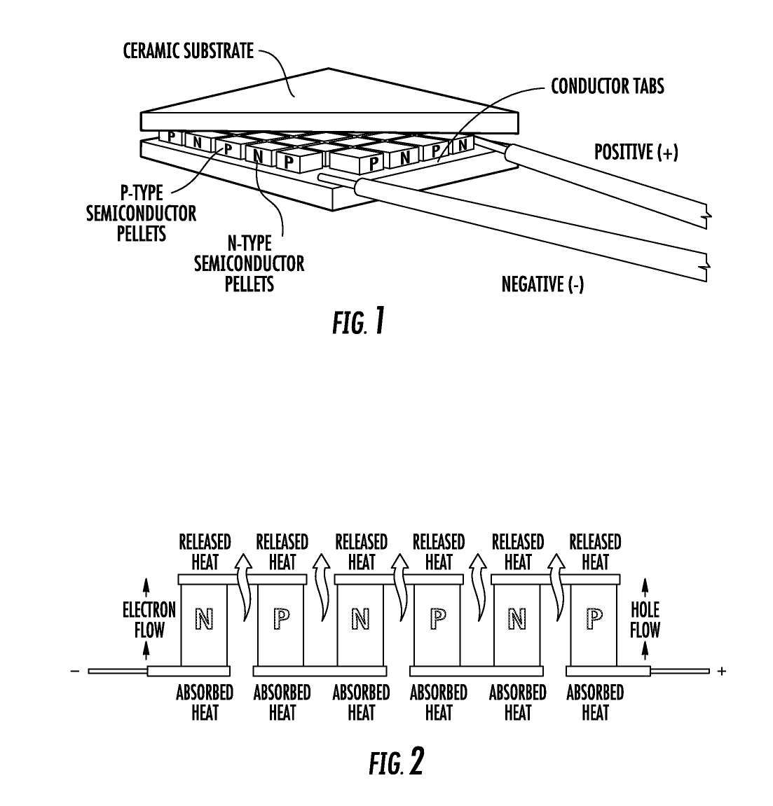

Description will now be given with reference to the attached FIGS. 1-9. It should be understood that these figures are exemplary in nature and in no way serve to limit the scope of the invention, which is defined by the claims appearing hereinbelow.

As shown in FIG. 1, a thermoelectric generator such as a Peltier device is something which is able to change a temperature differential into voltage (Seebeck Effect), and when a current is run through the device, opposite sides of the tile have a temperature difference (one side will be hot and the other side will be cold). The thermoelectric generator of FIG. 1 is a common configuration called a Peltier tile.

Referring to FIGS. 1 and 2, the Peltier tile 10 itself is a ceramic coated tile with n-type and p-type semiconductors 15 and 16 coupled together with a junction of a metal such as copper between each pellet of semiconductor. Current is generated when electrons flow from the heat-absorbing side 12 to the heat-releasing side 14.

Both n-type semiconductors 15 and p-type semiconductors 15 are doped or mixed with specific amounts of impurity. In an n-type semiconductor, each impurity atom produces a free electron which can drift to produce an electrical current. In a p-type semiconductor, each impurity atom has a hole in the valence band suitable for receiving an electron, e.g., one drifting off of an n-type semiconductor. Electrons from the n-type semiconductor flow through to the holes of the p-type semiconductor, thereby producting current. The charge and the heat flow in the same direction.

A typical Peltier tile is model TEC1-12706 manufactured by Hebei I.T. (Shanghai) Co., Ltd. It is 40 mm×40 mm×3.9 mm thick. The ceramic is alumina (Al₂O₃), and the solder is bismuth tin (BiSn). Other models and manufacturers are available, of course, however the TEC1-12706 is nicely dimensioned to fit behind a smart watch casing on a person's wrist, as will be explained below. The invention contemplates any existing type of thermoelectric generator now in existence or to be developed in the future.

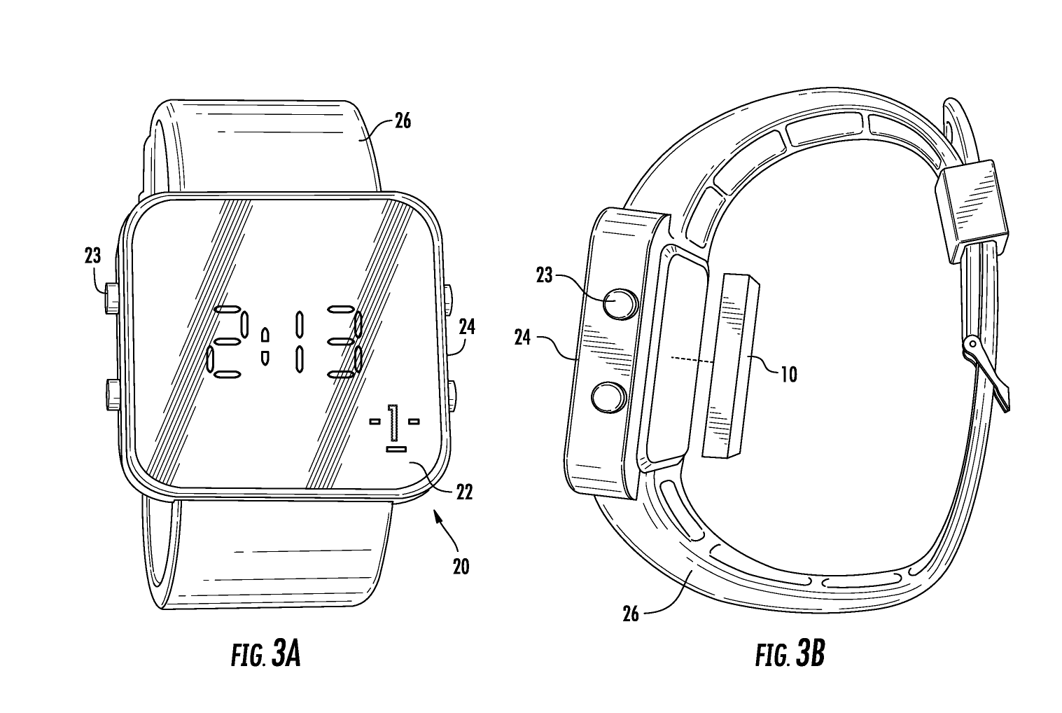

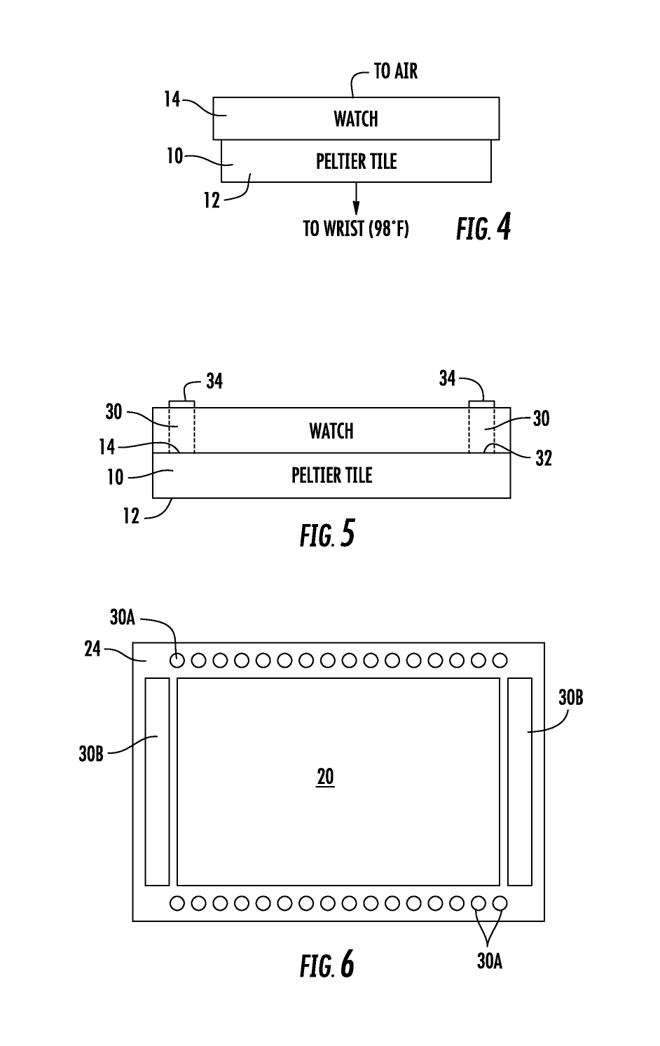

As shown in FIGS. 3A-B, a wearable electronic device such as a smart watch 20 may preferably include a touchscreen 22, buttons 23, and related circuitry substantially surrounded by a casing 24. Existing models of smart watches include the aforementioned GALAXY GEAR 2 NEO manufactured by SAMSUNG of Seoul, Korea, the APPLE WATCH manufactured by APPLE, INC. of Cupertino, CA, and others. Band 26 or a similar securing mechanism secures the watch 20 to the user, e.g., on the wrist or the like. As shown in FIGS. 3B and 4, Peltier tile 10 is disposed on an obverse or rear side of casing 24 behind watch 20. The heat-absorbing side 12 of Peltier tile 10 is positioned to be flush against or very close to (i.e., in thermal communication with) the skin of the body of the user, which is typically at approximately 98° F. In this way, heat-absorbing side 12 receives heat from the wearer's body via conduction, convection, radiation, and/or a combination thereof. The heat-releasing side 14 is disposed facing watch 20, i.e., in an environment typically having a temperature lower than 98° F. Because of the temperature differential between heat absorbing side 12 and heat releasing side 14, current is generated that can recharge the battery 28 of smart watch 20 while smart watch 20 is being worn, i.e., is not plugged into a wall charger or a computer via, e.g., a USB port (see FIG. 7). This will prolong the usable period of the device between charges and cause the consumer to use less electricity from a public utility to recharge the device.

Given that millions of wearable electronic devices have been sold already with millions more expected to be sold, the aggregate energy savings is significant.

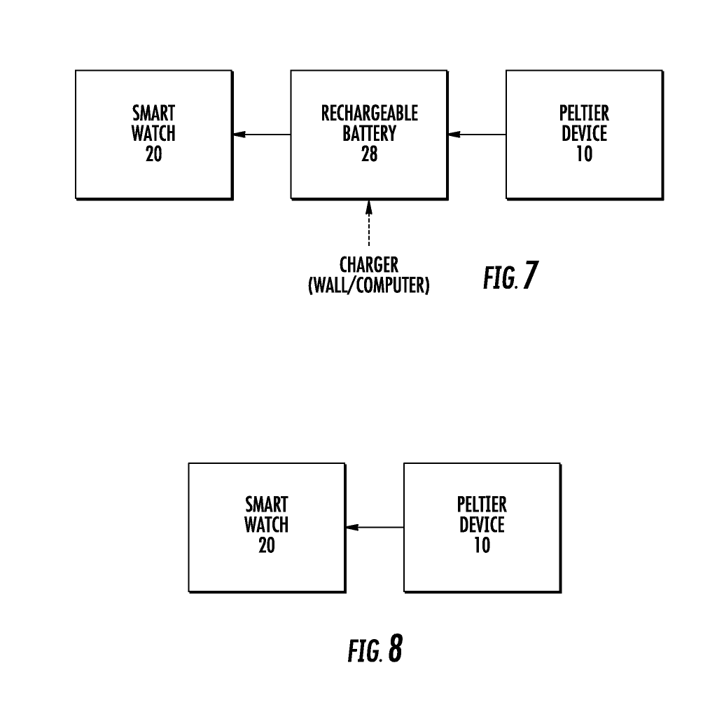

So as to maximize the heat releasing ability of heat releasing side 14 and/or to obtain as low a temperature as possible on heat releasing side 14 (e.g., as close to ambient air as possible), at least one fin 30 (see FIGS. 5 and 6) may be provided atop heat releasing side 14 to draw heat away from tile 10 and/or to put the heat releasing side 14 in thermal communication with ambient air. Fins 30 have a proximal end 32 that is in contact with or substantially close to heat releasing side 14 of tile 10, i.e., proximal end 32 is in thermal communication with heat releasing side 14 (e.g., via conduction, convection, radiation, etc.). At the other end, fins 30 have a distal side 34 that is in contact with or substantially close to ambient air, i.e., distal end 34 is in thermal communication with ambient air (e.g., via conduction, convection, radiation, etc.). As shown in FIGS. 5 and 6, in one embodiment of the invention, fins 30 are disposed in and pass through casing 24 surrounding smart watch 20.

The fin or fins may take any convenient or practical shape. For example, in FIG. 6, fins 30A are multiple, discrete cylindrical shaped disposed along the sides of casing 24. The multiple discrete fins 30A may be of any practical cross-sectional shape, e.g., circular, square, rectangular, hexagonal, irregular, etc. As another example, fins 30B are substantially continuous along at least part of the length of a side of the casing 24 and Peltier tile 10. Fins may be provided along the entirety of the perimeter of the casing and Peltier tile and may be completely continuous, discrete and multiple, or a combination thereof. Because the tops of the fins are optionally visible from the top or outward-facing surface of the device, the fins can be made into decorative shapes as well, e.g., letters spelling the name of the model/brand of the watch, designs, patterns, etc.

FIG. 9 depicts another wearable electronic device utilizing the invention. In this case, the device is an eyeglasses computer 100 such as made by GOOGLE, INC. of Mountain View, CA under the name GOOGLE GLASS. Eyeglass computer 100 includes a frame 104, two lenses 110 and 112, and arms 114 and 116 like a normal pair of eyeglasses. However, at least one of the lenses 110 and 112 may include a display screen or component for showing information 130. A camera 134 may also be provided for enabling the device to pull in visual data from the surroundings. According to the invention, one or more thermoelectric generators such as Peltier devices 120, 122 may be provided on a rear/underside of the device so that their heat absorbing sides are in thermal communication with the skin of the face of the user. For example, Peltier device 120 is provided on one or both arms 114 and 116 to be in thermal communication with the side/temple region of the user's head, and Peltier device 122 is provided on the bridge of frame 104 to be in thermal communication with the forehead/bridge region of the user's face. In every other respect, this embodiment is similar to the smart watch embodiments shown in the other figures. Fins are preferably provided through arm 114, 116 or frame 104 in the same manner as described above, i.e., one end is in thermal communication with the heat-releasing side of Peltier devices 120, 122, while the other end of the fin is in thermal communication with the ambient air.

The invention is not limited to smart watches and eyeglass computers but is suitable for any wearable electronic device, including rings, bracelets, chest badges, necklaces, anklets, earphones, headphones, arm bands (e.g., for holding and now charging electronic devices such as cell phones, music players, etc.), head bands, and the like. The invention is also suitable for body carriers for other existing personal electronic devices such as cell phones, digital music players, etc. In that variation, a device-holding armband or resilient sleeve, similar to those worn by people exercising, is provided with the thermoelectric generator which is connectable in electrical communication with the personal electronic device (which is now “wearable”, as it is being worn in the arm band/sleeve, etc.). Further, the fins shown in the drawings abut the Peltier tile and project slightly beyond the top/upper surface of the case; however, the fin(s) can also be flush or slightly recessed from the top/upper surface and/or a short distance away from the Peltier tile and still be in thermal communication (e.g., via conduction, convection, radiation, etc.) with the ambient air and the Peltier tile respectively.

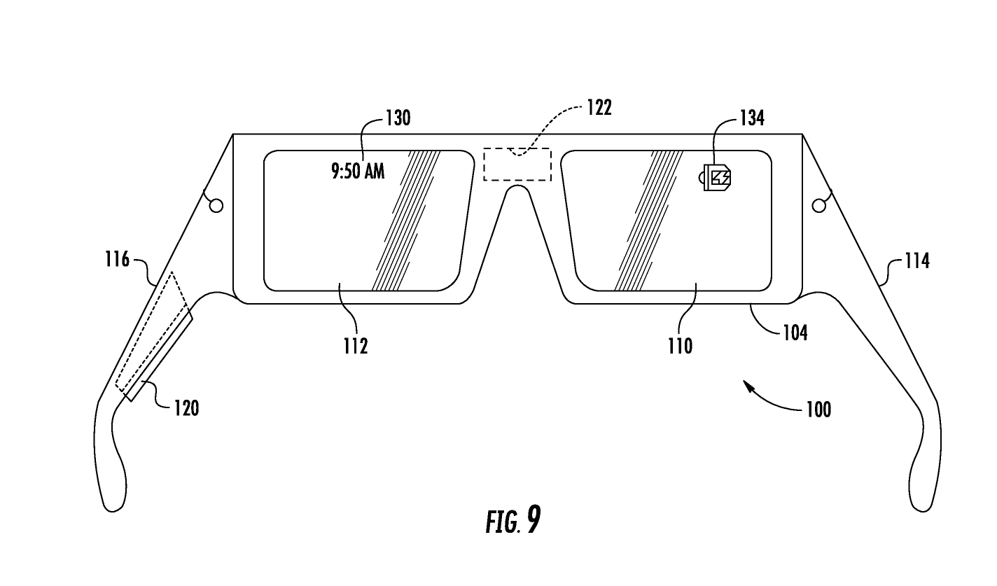

Regardless of the configuration of the electronic device being worn, depending on the size and efficiency of tile 10/120/122, the current generated in tile 10/120/122 by the body heat of the wearer might be sufficient to maintain battery 28 (see FIG. 7) in equilibrium so that it is being charged at substantially the same rate that it is discharging in powering the wearable electronic device. As another alternative, the current generated in tile 10 by the body heat of the wearer might not be sufficient to maintain the battery in equilibrium, but the battery will be discharging at a slower rate than it would otherwise in powering a smart watch, eyeglass computer, or other wearable devices. In both cases, battery life is extended, and less public utility power is used to recharge the device. As another alternative, the tile 10 might be sufficient to power the watch entirely and avoid the need for a separate battery or any public utility power at all (see FIG. 8).

Having described certain embodiments of the invention, it should be understood that the invention is not limited to the above description or the attached exemplary drawings. Rather, the scope of the invention is defined by the claims appearing hereinbelow and includes any equivalents thereof as would be appreciated by one of ordinary skill in the art.

What is claimed is:

1. A wearable electronic device, comprising:
a casing;
electronics disposed within said casing; and
a thermoelectric generator in electrical communication with said electronics and having a heat absorbing side in thermal communication with the wearer of the wearable electronic device when the wearable electronic device is being worn, and a heat releasing side,
wherein, when said wearable electronic device is worn by a wearer, body heat from the wearer is absorbed by said heat absorbing side and converted into electricity by said thermoelectric generator which at least partially powers said electronics.

2. A wearable electronic device in accordance with claim 1, further comprising a battery in electrical communication with said electronics and said thermoelectric generator, wherein electricity generated by said thermoelectric generator is provided to said battery.

3. A wearable electronic device in accordance with claim 1, further comprising at least one fin, in thermal communication with said heat releasing side, drawing heat away from said thermoelectric generator when said wearable electronic device is being worn.

4. A wearable electronic device in accordance with claim 3, said fin having a proximal end in thermal communication with said heat releasing side and a distal end in thermal communication with ambient air.

5. A wearable electronic device in accordance with claim 4, said fin being disposed substantially through said casing with said distal end terminating substantially at a top side of said casing.

6. A wearable electronic device in accordance with claim 2, wherein said thermoelectric generator is a supplemental power source and the electricity generated by said thermoelectric generator is substantially sufficient to maintain said battery in equilibrium so that said battery is being charged at substantially the same rate that said battery is discharging in powering said wearable electronic device.

7. A wearable electronic device in accordance with claim 2, wherein said thermoelectric generator is a supplemental power source and the electricity generated by said thermoelectric generator is slowing the discharge rate of said battery.

8. A wearable electronic device in accordance with claim 1, wherein said thermoelectric generator generates enough electricity to act as a primary power source for said wearable electronic device.

9. A wearable electronic device in accordance with claim 1, wherein said wearable electronic device comprises at least one of a smart watch or an eyeglass computer.

10. A wearable electronic device in accordance with claim 1, wherein said thermoelectric generator comprises a Peltier device.

11. A power source for a wearable electronic device having a casing and electronics disposed within the case, the power source comprising:
a thermoelectric generator in electrical communication with the electronics and having a heat absorbing side in thermal communication with the wearer of the wearable electronic device when the wearable electronic device is being worn, and a heat releasing side,
wherein, when the wearable electronic device is worn by a wearer, body heat from the wearer is absorbed by said heat absorbing side and converted into electricity by said thermoelectric generator which at least partially powers the electronics.

12. A power source for a wearable electronic device having a casing and electronics disposed within the case in accordance with claim 11, further comprising a battery in electrical communication with the electronics and said thermoelectric generator, wherein electricity generated by said thermoelectric generator is provided to the battery.

13. A power source for a wearable electronic device having a casing and electronics disposed within the case in accordance with claim 11, further comprising at least one fin, in thermal communication with said heat releasing side, drawing heat away from said thermoelectric generator when the wearable electronic device is being worn.

14. A power source for a wearable electronic device having a casing and electronics disposed within the case in accordance with claim 13, said fin having a proximal end in thermal communication with said heat releasing side and a distal end in thermal communication with ambient air.

15. A power source for a wearable electronic device having a casing and electronics disposed within the case in accordance with claim 14, said fin being disposed substantially through the casing with said distal end terminating substantially at a top side of the casing.

16. A power source for a wearable electronic device having a casing and electronics disposed within the case in accordance with claim 11, wherein said thermoelectric generator comprises a Peltier device.

17. A method of powering a wearable electronic device having a casing and electronics disposed within the casing, comprising the steps of:
providing a thermoelectric generator in electrical communication with the electronics and having a heat absorbing side in thermal communication with the wearer of the wearable electronic device when the wearable electronic device is being worn, and a heat releasing side;
absorbing body heat from the wearer into the thermoelectric generator;
converting the absorbed body heat into electricity by the thermoelectric generator; and
at least partially powering the electronics with the electricity generated by the thermoelectric generator.

18. A method of powering a wearable electronic device having a casing and electronics disposed within the casing in accordance with claim 17, further comprising the steps of:
providing a battery in electrical communication with the electronics and the thermoelectric generator; and
providing the electricity generated by the thermoelectric generator to the battery.

19. A method of powering a wearable electronic device having a casing and electronics disposed within the casing in accordance with claim 17, further comprising the steps of:
providing at least one fin, in thermal communication at a proximal end with the heat releasing side; and
drawing heat away from the thermoelectric generator via the fin.

20. A method of powering a wearable electronic device having a casing and electronics disposed within the casing in accordance with claim 19, further comprising the step of disposing a distal end of the fin in thermal communication with ambient air.
